(19) United States
(12) Patent Application Publication
(10) Pub. No.: US 2012/0168819 A1
(43) Pub. Date: Jul. 5, 2012

(54) Semiconductor pillar power MOS

(76) Inventors: Fabio Alessio Marino, San Jose, CA (US); Paolo Menegoli, San Jose, CA (US)

(21) Appl. No.: 12/930,239

(22) Filed: Jan. 3, 2011

(51) Int. Cl. H01L 29/78; H01L 21/336

(52) U.S. Cl. 257/192; 438/268; 257/329; 257/E29.262; 257/E21.41

(57) ABSTRACT

A novel semiconductor power transistor is presented. The semiconductor structure is simple and is based on a multi-gate vertical MOS configuration with multi semiconductor pillars, so that the control on the carrier transport is enhanced and the specific on-resistance per area is reduced. Furthermore, due to its particular geometry, the parasitic resistances due to the source/drain junctions, are also drastically reduced with respect to standard CMOS technologies. It offers the advantage of extremely lower on-resistance for the same silicon area while improving on its dynamic performances. The novel structure does not require Silicon On Insulator technologies and can be built using the standard Bulk CMOS process technology. This characteristic improves the thermal properties of the device which are extremely important in power applications.

### BACKGROUND OF THE INVENTION

1. Field of the Invention

The present invention is in the field of semiconductor structures. The present invention is further in the field of semiconductor structures of transistor devices. The present invention further relates to the field of integrated power devices and circuits. The implementation is not limited to a specific technology, and applies to either the invention as an individual component or to inclusion of the present invention within larger systems which may be combined into larger integrated circuits.

2. Brief Description of Related Art

The semiconductor transistor is the most important component for large integrated circuits. The complementary CMOS components used in current integrated circuit process technologies have undergone a continuous shrinking of the silicon area needed for elementary components, however the need to further improve on its general performance while reducing its cost is still a necessity that poses a significant challenge.

In particular, in the area of power integrated circuits the silicon area occupied by the power transistors and their performance is more and more important in several applications. A very critical parameter for power transistors in integrated circuits is their specific R_{Dson}, measured in Ω*mm². The silicon area is directly proportional to the cost of the integrated circuit and a low on-resistance is always desirable to increase the efficiency of the circuit and to reduce the power dissipation and therefore the temperature of the chip.

Typically the power transistors utilized in modern integrated circuits are constituted by large arrays of MOSFET or Lateral Diffused MOS devices effectively connected in parallel. Generally these transistors are used in applications that require high currents. The efficiency of a device employing power transistors is increased by minimizing the power losses in the system. In particular for switching power converters the optimization of the process technology and of the semiconductor structures to match the electrical characteristics of the system is paramount to achieve high efficiency.

The most important Figure Of Merit (FOM) of a power transistor in specific power applications is the R_{Dson}*Q of the transistor, where R_{Dson} is the on-resistance while Q is the charge associated with the gate capacitance (C*V). This FOM is directly associated with the time constant of the device. The lower the R_{Dson} and the gate charge, the higher the achievable efficiency. In conventional CMOS technology, this FOM is independent from the silicon area since a lower R_{Dson} deriving by an increase of the device size is generally correlated with an increase of the gate capacitance by the same amount.

On the other hand the cost in terms of occupied silicon area is a very important parameter and any method or technology to reduce the cost of the power device maintaining the same FOM (therefore increasing the current density per area) is very desirable. One means for increasing the current density is to increase the overall channel area of a transistor.

As mentioned above, the most studied prior art of semiconductor transistors that are used in power application comprises MOSFETs, Laterally Diffusion MOS devices (LDMOS) and High Electron Mobility Transistors including III-V materials. The resistance offered by these devices when turned-on and their parasitic capacitances are very important to establish the device efficiency and speed.

The typical cross-sections of a conventional MOSFET is illustrated in FIG. 1. In general, power MOSFETs employ thicker oxides, deeper junctions, and have longer channel lengths with respect to signal MOS devices. This generally posts a penalty on the device performance such as lower transconductance and speed, which are strictly correlated with the Figure of Merit described above (R_{Dson}*Q).

Several prior art attempts to improve power MOSFET performance, so as to effectively obtaining low on-resistance components, have been documented. In particular, a device often used in power applications, which show several advantages over the conventional MOS structure is the Laterally Diffused MOS (LDMOS).

A typical cross-sections of an LDMOS is shown in FIG. 2. As the name implies, in the LDMOS transistor the channel length is determined by the higher diffusion rate of the p-doping (e.g. boron) compared to the n⁺-doping (e.g. phosphorus) of the source. This technique can yield very short channels without depending on the lithographic mask dimension.

The p-diffusion serves as channel doping and has good punch-through control. The channel is followed by a lightly doped n⁻-drift region. This drift region is long compared to the channel, and it minimizes the peak electric field. The electric field near the drain is the same as in the drift region, so the avalanche breakdown, multiplication, and oxide charging are lessened compared to conventional MOSFETs.

Such doping configuration enables the p-doped substrate to deplete this drift region at high drain bias. Yet at low drain bias its n-doping gives lower series resistance. This drift diffusion, thus behaves as a non linear resistor. At low drain bias, its resistance is determined by 1/nqμ, where n is the doping concentration, q is the elementary charge, and μ is the electron mobility in the semiconductor. At high drain bias, this region is fully depleted so a large voltage drop can be supported. This concept is called RESURF (reduced surface field) technology.

The main purpose of the present invention is to describe a novel structure of a power semiconductor transistor based on a multi-gate configuration, with a vertical channel region composed by a multiplicity of semiconductor pillars. This device offers the advantage of reducing silicon area and cost combined with improved performances in terms of on-resistance with respect to both conventional MOSFETs and LDMOS devices.

Generally the multi-gate configuration is used in integrated semiconductor transistors only to improve the control on the carrier transport in the device so as to effectively obtaining a better I_{ON}/I_{OFF} ratio with respect to more conventional MOS structures, rather than to increase the current density per silicon area.

In order to guarantee a high I_{ON}/I_{OFF} ratio, the dimensions of a multi-gate device must satisfy very strict specifications, which limit the amount of current that the device can support. This characteristic limits the use of these devices to particular applications, such as DRAM memory and high speed digital circuits. The most known prior arts using this approach comprise MOSFET with double, triple and all-around gate.

In a double gate MOS, aside the conventional gate, a second gate is present under the channel in order to improve the control on the channel modulation. An example of double gate MOS is reported in the patent application Yun (US 2007/0120200). In order to achieve the maximum control on the carrier transport, the thickness of the channel region is made thinner than the maximum extension x_{d} of the depletion region in the channel region. This device configuration requires a very complex fabrication process, usually involving silicon on insulator technology.

A triple-gate MOS has the structure illustrated in Anderson et al. (U.S. Pat. No. 7,247,908). This device has approximately the same performance of a double gate MOS, but it requires a simpler process technology since the alignment of the different gates is more easily achieved. However, differently from a double gate MOS, the channel width of a triple-gate MOS is limited. The distance between the two lateral gates must be smaller than the maximum extension of the depletion region. This limits the value of the horizontal dimension of the device. Furthermore, for process and cost related reasons, also the vertical dimension of the device is limited.

Another prior art example of enhanced gate control is the approach named “gate all-around MOS” shown in the patent application Masuoka et al. (US 2004/0262681). In this case, the gate terminal surrounds the whole channel, leading to an optimum channel control. However, also in this case, several physical and process limitations are present. In order to achieve the best control on the channel carrier transport, the distance between parallel sidewalls of the device channel must be smaller than the maximum extension of the depletion region. This leads to a limit on the maximum extension of the total channel width.

All these examples require a complex and costly process involving usually Silicon On Insulator technologies, which are still very expensive nowadays. A second problem is the alignment of the different gates of the device. Furthermore, since they are built on buried oxide, they cannot be used for power applications because of their very poor capability to dissipate heat. Silicon dioxide, for example has a thermal conductivity that is about 100 times smaller than the one for Silicon. Finally, as discussed above, since their main objective is to enhance the control on the carrier transport, they are not very efficient in saving silicon area with respect to the conventional CMOS technology.

The present invention does not require Silicon on insulator technology, neither has to guarantee a better I_{ON}/I_{OFF} ratio with respect standard MOS devices and, therefore, it is not limited on the channel dimensions. Furthermore, the present invention can be realized in standard CMOS process technology which makes the solution very cost attractive.

As mentioned above, another feature of the present invention consists in the fact that its main current conduction path is orthogonal with respect to the primary surface of the semiconductor substrate (rather than parallel to it). This is another characteristic that strongly distinguishes the present invention from the integrated power devices used nowadays in the power-electronic industry. Vertical MOS transistors for integrated circuits have been reported in literature only for DRAM memories applications.

An example in which a vertical double gate MOSFET is used as a memory cell transistor of a DRAM is proposed by Noble et al. (U.S. Pat. No. 6,818,937). In this structure, a capacitor is provided on an impurity diffusion layer on the top of the channel region making up a three-dimensional double gate transistor, and a bit line is located under an impurity diffusion layer under the channel region.

A method for manufacturing a vertical double gate MOS transistor for DRAM applications is also proposed by Oyu et al. (U.S. Pat. No. 7,670,911). Oyu et al. propose to use lower doped impurity regions for the drain and source regions and to increase the oxide thickness in the gate-drain and gate-source overlap regions, in order to lower the leakage current due to GIDL effects, which discharge the storing capacitor in the memory cell.

The cited prior art (Noble et al. and Oyu et al.) are not intended for power structure applications and, in fact, in power applications the improved I_{ON}/I_{OFF} ratio is irrelevant, therefore all the considerations about the channel dimensions are moot. Furthermore, the present invention is not limited to double gate MOS configurations. As such also the inclusion of a capacitor above the channel represents a major differentiation.

Power semiconductor devices are semiconductor devices used as switches or rectifiers in power electronic circuits (switch mode power supplies for example). They are also called power devices or when used in integrated circuits, they are called power ICs. In the field of integrated power transistors one of the most important parameter is the R_{DSon}*area of the utilized technology. The lower the R_{DSOn}*area, the lower is the cost of the device and the higher the speed of the transistor.

An interesting prior art that attempts to achieve higher current density for power transistors using vertical conduction is the Vertical DMOS (Double-diffused MOS) reported in FIG. 3. In this case the gate 15 is in common between two transistors connected in parallel, one on the left side of the gate and one on the right part of the gate. The device conduction is partially vertical and the device drain 19 is located in the lower part of the structure as shown in FIG. 3 which represents the back of the silicon wafer. This configuration is therefore only used in discrete power devices and the major limitation is that only one device per die can be utilized.

A similar prior art of discrete power devices which attempts to achieve higher density with vertical conduction configuration is the V-MOSFET illustrated in FIG. 4. In this case the gate 23 is in common between two vertical transistors connected in parallel, and built facing each other, one on the left side of the gate and one on the right part of the gate. Also in this case the drain 28 is formed under the channel and in the lower part of the structure which is the back of the die. Again the limitation is that only a single device per die can be implemented.

Although both the DMOS and the V-MOS prior art structures have at least a partial vertical conduction path which allows the reduction of the on-resistance with respect to conventional power MOSFET devices, they cannot be used in integrated circuits since they require a bottom drain contact. This unequivocally limits their application as standalone discrete components.

The main purpose of the present invention is to describe a novel structure of a semiconductor vertical transistor for integrated power circuits, that offers the advantage of much higher density even more than discrete configurations.

It is therefore a purpose of the present invention to describe a novel structure of a semiconductor transistor that offers the advantage of much higher density, reducing silicon area and cost combined with improved performances in terms of on resistance.

### SUMMARY OF THE INVENTION

The present invention describes a power transistor which has a multi-gate MOS structure, with a vertical channel region composed by an array of semiconductor pillars built perpendicular to the primary substrate surface, in order to increase the overall channel area of the transistor and reduce its specific on-resistance (R_{DSon}*area). Furthermore, the channel region of the device structure is placed in direct contact with the semiconductor substrate in order to improve the thermal properties of the device and to simplify the process required to build it.

In order to better understand this concept, let us consider the structure illustrated in FIG. 5, which represents a cross-section of the first embodiment of the present invention. As it can be seen, conventional device terminals (source, gate, drain and body) are present as in a conventional planar MOS device. However, the channel region of the transistor is composed by a multiplicity of semiconductor pillars in which the current flows in the direction perpendicular to the primary surface of the semiconductor substrate rather than parallel to it.

In FIG. 5 an individual pillar 34 is highlighted for clarity. Each of the semiconductor pillars 34 is surrounded by an insulator layer 36, and a gate layer 37. All the gate layers 37 are directly coupled together in the third dimension (not shown) in order to form the gate terminal of the device.

Differently from conventional planar MOS structures, the channel length of the present invention corresponds to the height of the channel region and it is determined by the implant characteristics (e.g. impurity concentration, diffusivity and implants depth) of the source and drain regions rather than the minimum feature size of the process technology used to realize the device. This is a great advantage in power devices, which usually are using old technologies to reduce fabrication costs.

The multi-gate configuration offers several advantages. Among all, the use of this configuration exploits the bulk mobility of the device (reducing the surface roughness impurity scattering) and obtains multiple conductive channels. This leads to an increase of the conductivity of the device when it is operating in on-state (triode region).

The device channel is composed by an array of semiconductor pillars in order to concentrate the maximum number of conductive channel per silicon area. This particular feature combined with multiple gates, leads to an extremely large reduction of the device specific on-resistance.

Although for power applications, as mentioned above, obtaining the maximum control on the carrier transport is not required, the thickness of the channel region of each semiconductor pillar can be made thinner than the maximum extension x_{d} of the depletion region in order to achieve other advantages. Since the channel of the present invention is composed by a multiplicity of semiconductor pillars, this condition does not limit the device total channel dimensions, neither its specific on-resistance.

If this condition is respected, the device behaves as a fully depleted SOI MOS, the channel regions are always depleted during the normal operation of the device, and the device does not include a body (back gate) terminal and therefore a body-diode.

This is a great advantage in power application and in particular in the switching power conversion field, because the lack of the body diode removes the reverse recovery charge normally associated with the junction capacitance of the body diode. The elimination of the reverse recovery charge allows a faster switching transition and most importantly a more efficient utilization of the device in high frequency applications.

In the case of driving inductive loads the drain of the switching power device is potentially subject to negative voltages with high dv/dt. These negative voltage spikes are generally troublesome because they can trigger the activation of parasitic transistors that can affect the operation of the circuit. The structure depicted in FIG. 5 offers the advantage that the drain terminal can be selected to be the one at the top of the channel thus eliminating all the parasitic actions. This offers the advantage that the device does not have to be isolated in a separate N-well and removes the need for complex anti-collection barrier structures.

Another important consideration relative to the power applications is that for high frequency power integrated circuits generally the body of the transistor is contacted closely to prevent the lateral parasitic npn in parallel to the mos from turning on. If the structure of FIG. 5 operates in fully depletion mode, the parasitic npn cannot be activated therefore the elimination of the body contacts increases further the density of the device effectively improving its specific R_{Dson}.

In order to further relax the specifications on the semiconductor pillars dimensions to maintain a fully depleted behavior, the gate electrodes can be doped with p-type impurities for an n-MOS, and with n-type impurities in the p-MOS configuration.

The vertical geometry of the device allows the reduction of the parasitic junction resistance and capacitance associated with the Source and Drain terminals. No silicon on insulator process technology is required, and this significantly lowers the cost of the device.

Furthermore, since the device is in direct contact with the semiconductor substrate, the thermal dissipation of the device heat is more efficient with respect to the conventional multi-gate FET in silicon on insulator technologies, whose channel region is built on insulator materials with an extremely low thermal conductivity.

The angle θ represented in FIG. 5, can be made greater or smaller than 90 degree, in order to simplify the device fabrication. For instance, in the case where doping implantations are necessary to adjust the threshold voltage of the device, the side-walls of the pillars can be made inclined in order to obtain a better doping distribution in the doped region.

In order to increase the carrier mobility in the device, the channel region can be doped with very low concentrations of p-type impurities or with n-type doping as illustrated in FIG. 6. In this case, the impurity scattering and the surface roughness scattering rates are greatly reduced. Using a p-doped poly-silicon gate layer, instead of the classical n-doped ones, the semiconductor device assumes a positive threshold voltage and behaves as an enhancement MOS transistor.

Furthermore the present invention can be realized also with drain extensions as depicted in FIG. 7, in order to use short gate lengths and still maintain the electric filed at the gate-end within reasonable values in high voltage applications.

As it can be seen from FIG. 7, differently from an LDMOS, no extra masks are needed in order to create the drain extension. The mask used to perform the drain implant can be used also to obtain the drift region under it. This eliminates scalability problems that can rise from the misalignment of the masks in scaled process technologies.

As illustrated in FIG. 8, the lower n+ region can be divided in several regions placed next to each other in order to connect the channel regions of the semiconductor pillars directly to the substrate region. This configuration allows the biasing of the channel regions comprised in each semiconductor pillar eliminating eventual floating body effects that could take place in the case in which the channel regions are not completely depleted during the normal operation of the device.

In FIG. 9, FIG. 10, FIG. 11, and FIG. 12 are depicted different possible layout configurations for the structures described above. The dimensions and the shape of the pillars cross-sections determine the specific on-resistance improvement with respect to the more conventional MOS of FIG. 1.

In FIG. 9 is represented a parallel plate configuration, where the different gate fingers are parallel to each other. In this case each pillar's conductivity is controlled by two lateral gates.

Aside from the parallel plate configuration of FIG. 9, the present invention can be realized with many different pillar shapes. Each semiconductor pillar of the device can have three, four, six or more gates.

As illustrated in FIG. 10, combining for example triangular pillars, a significant improvement of the specific on-resistance can be achieved. The silicon area between the pillars is fully utilized, and the number of vertical conductive channel per silicon area is maximized.

In FIG. 11 and FIG. 12 are depicted other two possible embodiments of the invention. In FIG. 11 the semiconductor pillars have an hexagonal cross section, while FIG. 12 shows an embodiment of the present invention with rectangular pillars.

Assuming that the semiconductor pillars constituting the device have a triangular cross section with edges wide 2A=2L each, where L is the minimum feature size of the technology available, a single triangular semiconductor pillar will use

Area triangle=(2L)*[2L*sin(60 deg)]/2=\sqrt{3}/2*L² silicon area

If we consider a device with 10 semiconductor pillars as illustrate in FIG. 10, and we take into account the lateral overhead necessary for the source terminal, we will need about 10*\sqrt{3}/2*L²+10*L²≈20*L² of silicon area, which is about the silicon area occupied by a single planar MOS whose channel width is 4*L.

Since each semiconductor pillar allows an improvement of the on-resistance by a factor of at least 4 (three conductive channels of width L and more control on the carrier transport) with respect to a conventional planar channel configuration, a pillar MOS with 10 triangular pillars will have a specific on-resistance 10 times smaller than a simple planar MOSFET.

The embodiment of FIG. 10 allows improvement of the performance of a single device by a factor 10 or more. Similar calculations can be done for the other pillar shapes illustrated in FIGS. 11 and 12.

All the device structures described above can be obtained with a simple extra process step. By means of a simple silicon etching step at the beginning of the MOS process, the device semiconductor pillars can be formed on the substrate surface. The other process steps (implantations, gate oxide thermal growth, and gate deposition) will remain unchanged with respect to a conventional CMOS process technology. This makes the present invention very cost attractive.

Aside from CMOS bulk technology, the present invention can be realized also with an High electron mobility transistor configuration including III-V materials in the fabrication process. This can be an attractive alternative to the Silicon FET configuration in some particular applications.

When the present invention is used for power transistor structures particular attention has to be paid to thermal considerations. It is important to avoid any hot spots or thermal positive feedbacks. Typically the thermal flow in a power transistor utilized in integrated circuits is occurring from the channel area to the substrate (when a package is used) or to the connecting terminals at the surface (bumps) for CSP (chip scale package).

The fact that the present invention offers lower specific R_{Dson} can be viewed as a means of producing more efficient power devices and therefore having less power to be dissipated for the same silicon area. But it could also be interpreted as a means to reduce the silicon area for the same on resistance. In that case the current density is increased and the need to dissipate more power in lower silicon area could present some technical challenges.

Similarly the higher current density in the device may pose problems with the electro-migration limitations of the metal connections involved. The general advantage of lower channel resistance of the present invention puts more emphasis on using thick metals for power interconnections and metals like copper in order not to transfer the general resistivity problem to the main transistors terminals connections.

It is therefore an object of the invention to increase the packing density and to improve the device performance by using vertical transport, multi-gate control, and multi-semiconductor-pillar structures. It is a further object of the invention to increase the speed of the transistor by reducing the parasitic capacitances and contact resistances.

As is clear to those skilled in the art, this basic system can be implemented in many specific ways, and the above descriptions are not meant to designate a specific implementation.

### BRIEF DESCRIPTIONS OF THE DRAWINGS

The features, objects, and advantages of the present invention will become apparent upon consideration of the following detailed description of the invention when read in conjunction with the drawings in which:

FIG. 1 shows a cross section view of a conventional MOSFET built in CMOS technology (prior art).

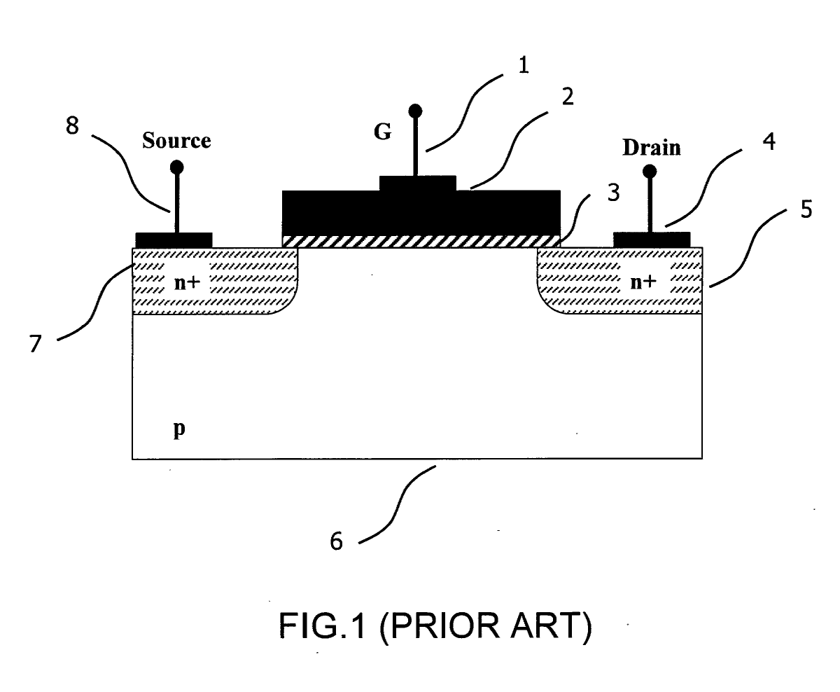

FIG. 2 shows a cross section view of a Lateral diffused MOS, where a drift region is present in order to decrease the electric field inside the device in high voltage applications (prior art).

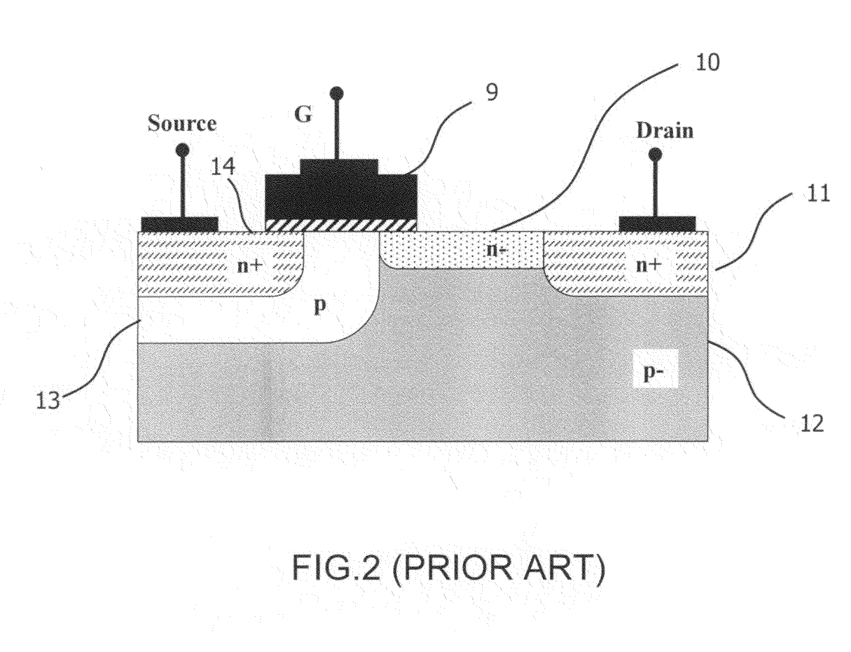

FIG. 3 shows a Vertical Double-diffused MOS, a discrete power device in which the carrier transport is partially vertical (prior art).

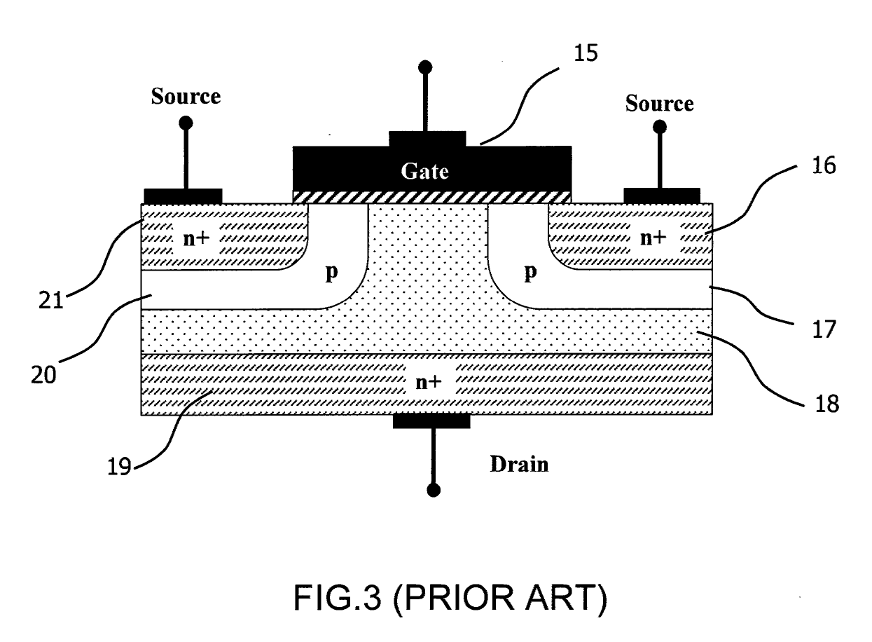

FIG. 4 shows a cross section view of a V power MOS, a discrete power device which can achieve high current densities. (prior art).

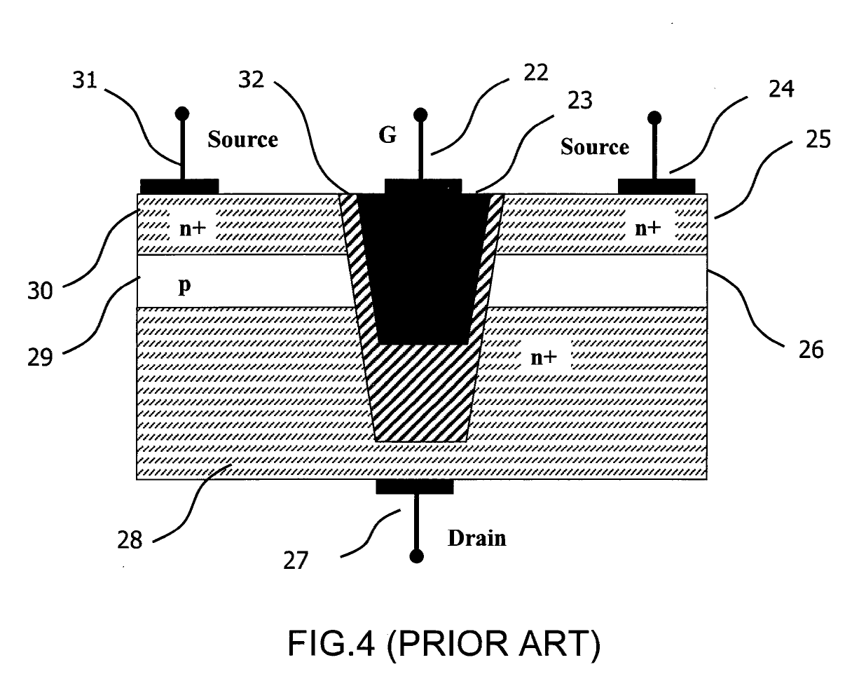

FIG. 5 shows a cross section view of a high power device according to the preferred embodiment of the invention.

FIG. 6 shows a cross section view of a high mobility power device according to a second embodiment of the invention.

FIG. 7 shows a cross section view of a power device with drain extension according to a third embodiment of the invention.

FIG. 8 shows a cross section view of a power device with the channel region connected to the substrate according to a fourth embodiment of the invention.

FIG. 9 shows a top view of the present invention in a parallel plate configuration according to a fifth embodiment of the invention.

FIG. 10 shows a top view of the present invention with triangular semiconductor pillars according to a sixth embodiment of the invention.

FIG. 11 shows a top view of the present invention with hexagonal semiconductor pillars according to a seventh embodiment of the invention.

FIG. 12 shows a top view of the present invention with rectangular semiconductor pillars according to an eighth embodiment of the invention.

### DETAILED DESCRIPTION OF SPECIFIC EMBODIMENTS

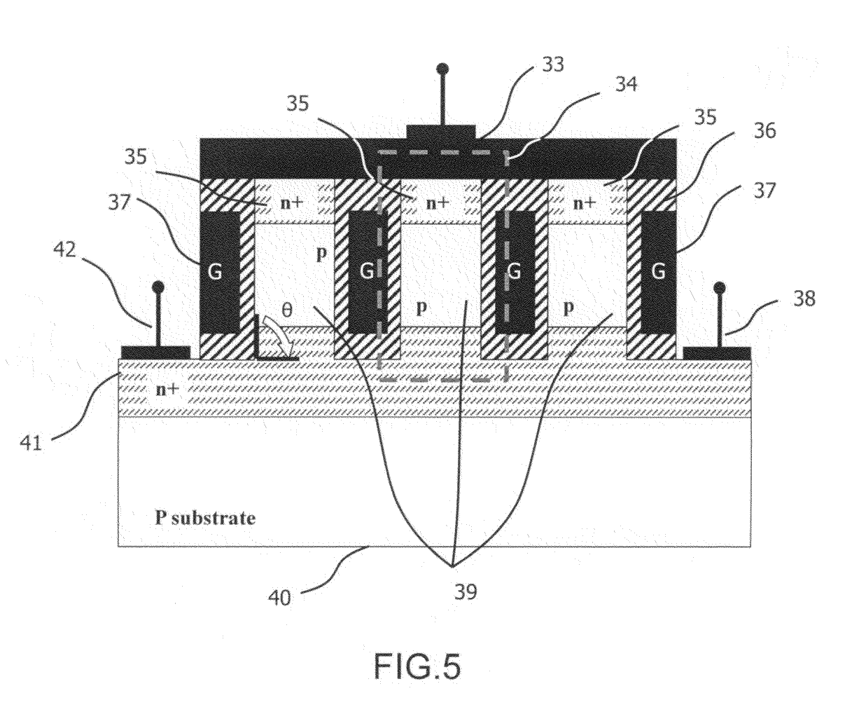

A FIG. 5

FIG. 5 is showing the first embodiment of the invention. The n⁺-type region 41 defines the source (or drain) region whereas the n⁺-type regions 35 are coupled all together through the metal layer 33 to form the drain (or source) of the transistor. The regions 36 correspond to the gate-oxide layers, and region 40 is the p-type substrate of the device. The gate electrodes (or terminals) 37, which may be built in poly-silicon or metal, are all connected together in the third dimension and form the gate of the transistor.

As it can be seen, differently from a conventional MOS transistor where the channel region is horizontal, the channel region of the present invention is vertical and composed by several semiconductor pillars.

The channel length of the device represents the height of the channel region and it is determined by the doping implants characteristics (e.g. impurity concentration, diffusivity and implants deepness) of the source and drain regions rather than the minimum feature size of the process technology used to realize the device. As mentioned above, this is a great advantage in power devices, that usually are using process technologies that are not the most advanced, to reduce the fabrication cost.

The multi-gate configuration allows the reduction of the surface roughness and impurity scattering, and the increase of the number of conductive channels. This leads to an increase of the conductivity of the device when it is operating in on-state conditions (triode region).

As it can be seen from FIG. 5, the device channel is composed by an array of semiconductor pillars in order to concentrate the maximum number of conductive channels per silicon area. This particular feature combined with the multi-gate configuration, leads to a very low on-resistance.

Although for power applications, as discussed above, obtaining the maximum control on the carrier transport is not required, the thickness of the channel region of each semiconductor pillar can be made thinner than the maximum extension x_{d} of the depletion region in the channel region in order to achieve other advantages. Since the channel of the present invention is composed by a multiplicity of semiconductor pillars, this condition does not limit the device total channel dimensions, neither its specific on-resistance.

If this condition is respected, the device behaves as a fully depleted SOI MOS, the channel regions are always depleted during the normal operation of the device, and the device does not include a body (back gate) terminal and therefore a body-diode.

This is a great advantage in power application and in particular in the switching power conversion field, because the lack of the body diode removes the reverse recovery charge normally associated with the junction capacitance of the body diode. The elimination of the reverse recovery charge allows a faster switching transition and most importantly a more efficient utilization of the device in high frequency applications.

In the case of driving inductive loads the drain of the switching power device is potentially subject to negative voltages with high dv/dt. These negative voltage spikes are generally troublesome because they can trigger the activation of parasitic transistors that can affect the operation of the circuit. The structure depicted in FIG. 5 offers the advantage that the drain terminal can be selected to be the one at the top of the channel thus eliminating all the parasitic actions. This offers the advantage that the device does not have to be isolated in a separate N-well and removes the need for complex anti-collection barrier structures.

Another important consideration relative to the power applications is that for high frequency power integrated circuits generally the body of the transistor is contacted closely to prevent the lateral parasitic npn in parallel to the mos from turning on. If the structure of FIG. 5 operates in fully depletion mode, the parasitic npn cannot be activated therefore the elimination of the body contacts increases further the density of the device effectively improving its specific R_{Dson}.

In order to further relax the specifications on the semiconductor pillars dimensions, maintaining a fully depleted behavior, the gate electrodes can be doped with p-type impurities for an n-MOS, and with n-type impurities in the p-MOS configuration.

The vertical geometry of the device allows the reduction of the parasitic junction resistance and capacitance associated with the Source and Drain terminals. No silicon on insulator process technology is required, and this significantly lowers the cost of the device.

Furthermore, since the device is in direct contact with the silicon substrate, the thermal dissipation of the device heat is more efficient with respect to conventional multi-gate FETs in silicon on insulator technologies, whose channel region is built on insulator materials with an extremely low thermal conductivity.

The angle θ represented in FIG. 5, can be made greater or smaller than 90 degrees, in order to simplify the device fabrication. For instance, in the case where doping implantations are necessary to adjust the threshold voltage of the device, the side-walls of the pillars can be made inclined with respect the primary substrate surface in order to obtain a better doping distribution in the doped region.

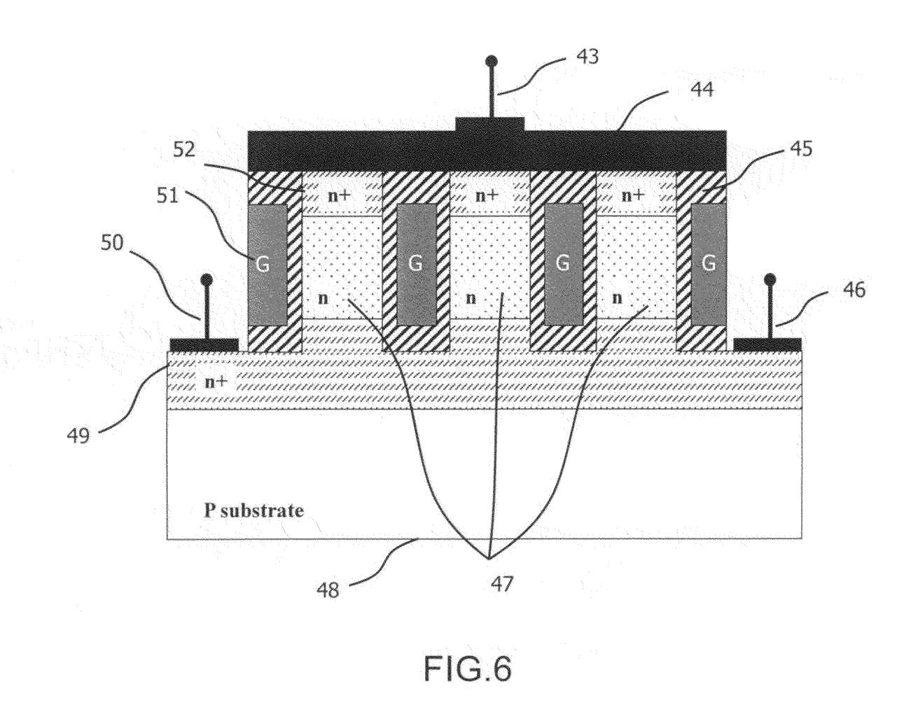

B FIG. 6

FIG. 6 is depicting the cross-section view of a power device according to a second embodiment of the invention. This structure is similar to the one shown in FIG. 6, with the exception that the channel regions 47 are n-doped and the gate layers 51 are p-doped. In this case, the impurity scattering and the surface roughness scattering rates are greatly reduced with respect to the structure of FIG. 5. This structure allows therefore the improvement of the carrier mobility in the device maintaining a positive threshold voltage and, therefore, an enhancement MOS behavior.

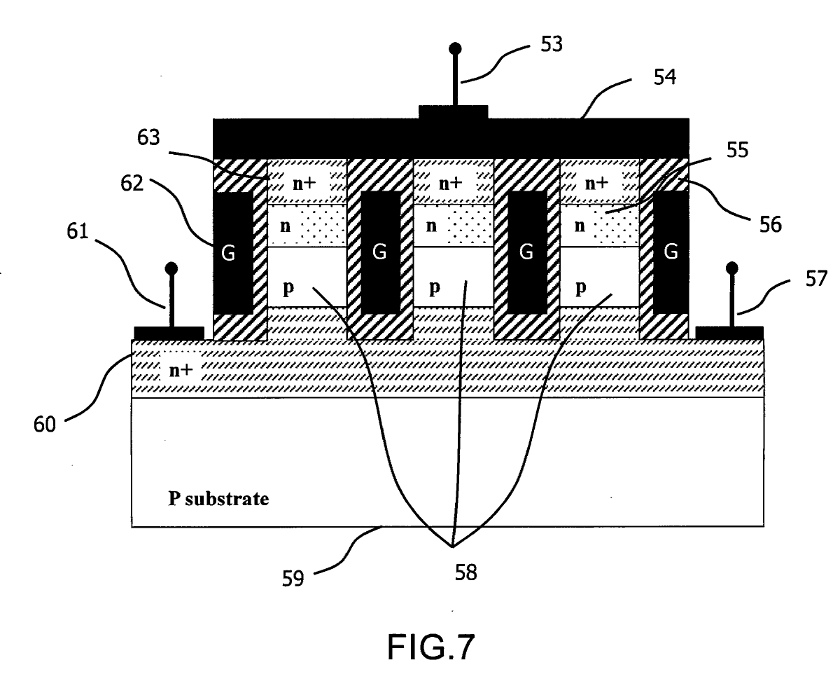

C FIG. 7

In FIG. 7 lightly n-doped diffusion regions 55 are present under the drain implants. These drift regions minimize the channel electric field at the gate-end side improving the reliability of the device in high voltage applications. The field near the drain is the same as in the drift regions, so avalanche breakdown, multiplication, and oxide charging are lessened compared to conventional MOSFETs.

Such doping configuration, as in the case of an LDMOS, enables the p-doped region to deplete these drift regions at high drain bias. Yet at low drain bias the n-doping gives lower series resistance. These drift diffusion regions, thus behave as non linear resistors. At low drain bias, their resistance is determined by 1/nqμ, where n is the doping concentration, q is the elementary charge, and μ is the electron mobility in the semiconductor. At high drain bias, these regions are fully depleted so a large voltage drop can be withheld.

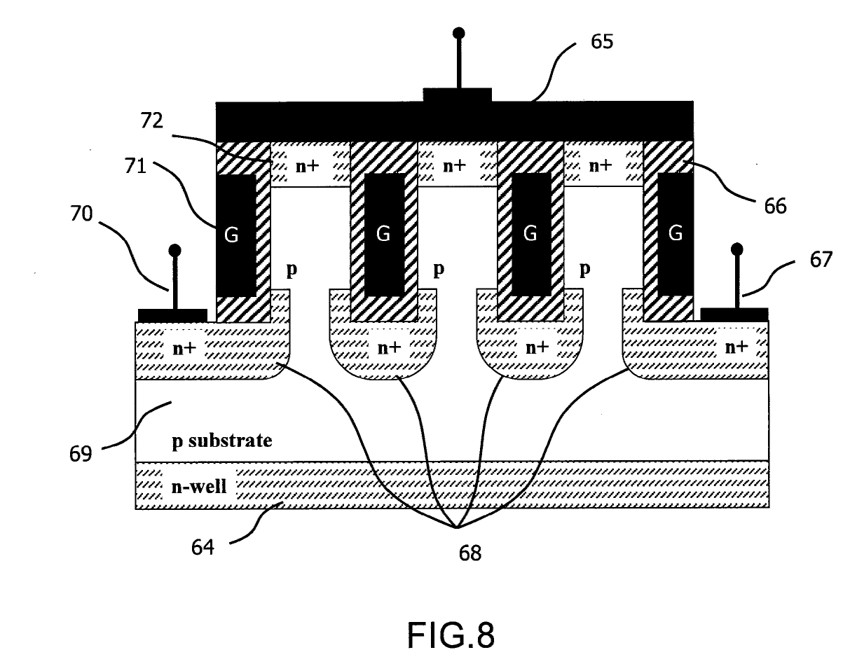

D FIG. 8

In FIG. 8 is reported a structure similar to the one depicted in FIG. 5, with the difference that the n+ region under the semiconductor pillars has been divided in separated regions placed apart from each other, in order to leave a p-doped path between the channel region of each semiconductor pillar and the substrate region.

This implant configuration can be used for all the structures discussed above, and allows the elimination of floating body effects, which could take place when the semiconductor pillars are made not thin enough to guarantee that the power device is always operating in fully depletion mode.

The structure of FIG. 8 has been formed inside an N-well 64 in order to isolate the device from the rest of the integrated circuit. This well can also be omitted if the application does not require it.

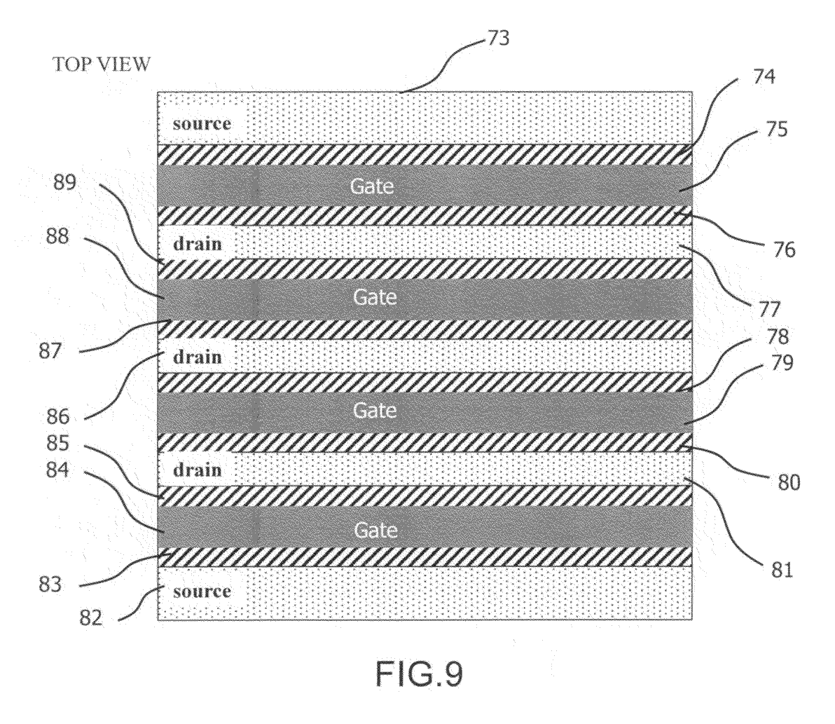

E FIG. 9

FIG. 9 is depicting a possible layout configuration for the present invention in parallel plate configuration. In such structure, each gate layer is in common between only two semiconductor pillars.

Aside from the parallel plate configuration of FIG. 9, the present invention can be realized with many different pillar shapes. Each semiconductor pillar of the device can have three, four, six or more gates.

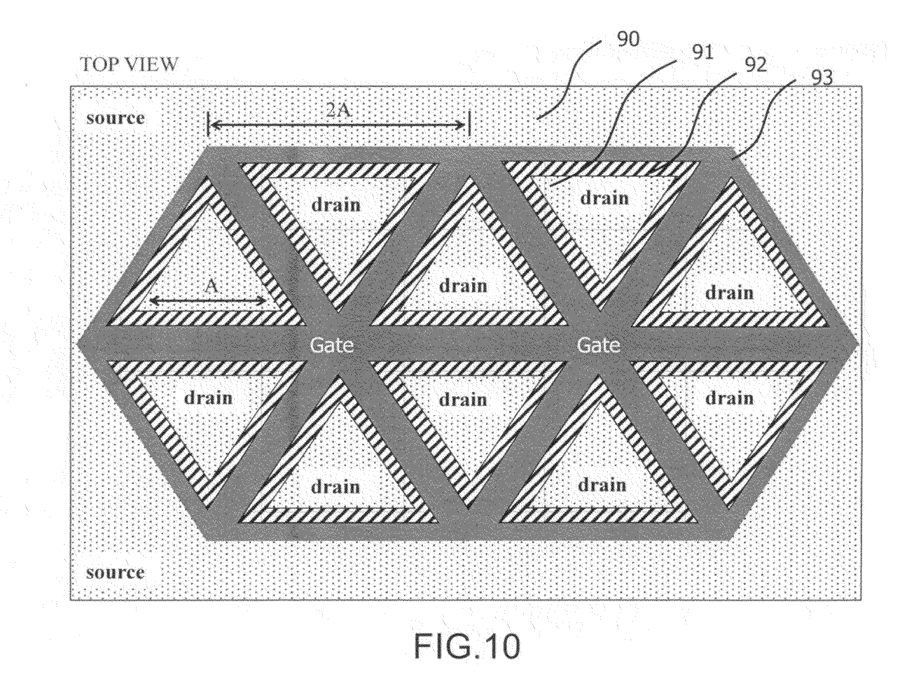

F FIG. 10

FIG. 10 shows the top view of a sixth embodiment of the invention. In this structure the semiconductor pillars have a triangular cross section which allows an extremely high number of conductive channels for silicon area. As it can be seen, the resulting structure is very compact.

As discussed above, the embodiment of FIG. 10 allows an improvement of the performance of a single device by a factor 10 or more. The silicon area between the pillars is fully utilized, and the number of vertical conductive channels per silicon area is maximized.

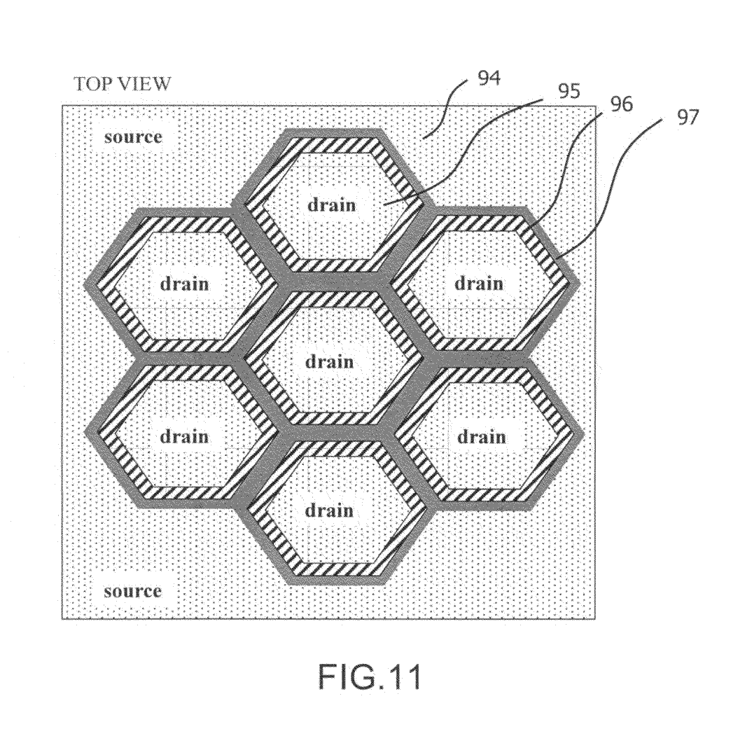

G FIG. 11

FIG. 11 shows the top view of a seventh embodiment of the invention. This structure is similar to the one illustrated in FIG. 10, with the exception that the semiconductor pillars have an hexagonal shape.

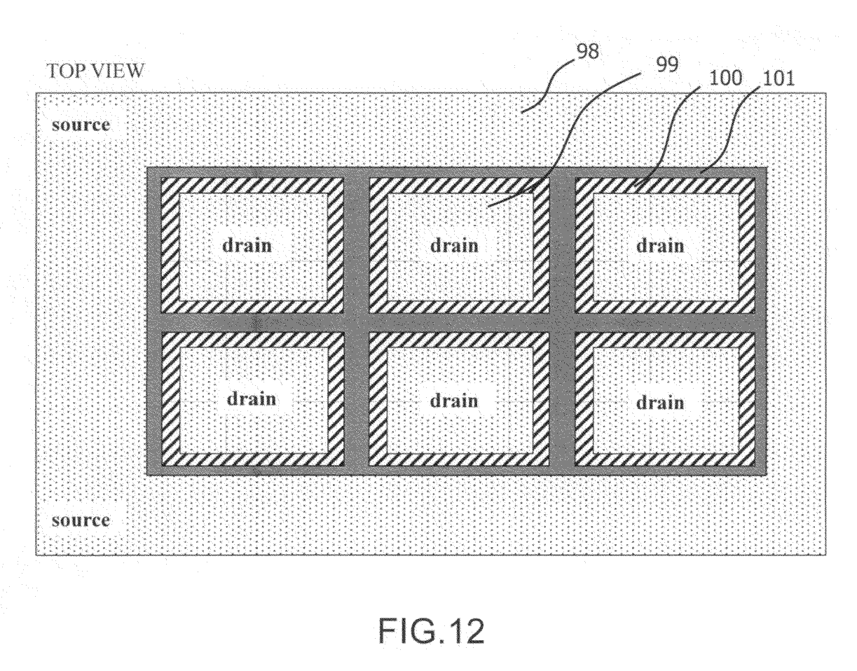

H FIG. 12

FIG. 12 shows the top view of an eighth embodiment of the invention. This structure is similar to the one of FIG. 10, with the exception that in this case the semiconductor pillars have a rectangular shape.

For all the FET structures described above, the p-channel version can be obtained by simply substituting the n-doped implants with p-type ones and vice-versa.

All the device structures described above can be realized in standard CMOS technology with a simple extra process step. By means of a simple silicon etching step at the beginning of the MOS process, the device semiconductor pillars can be formed on the substrate surface. The other process steps (implantations, gate oxide thermal growth, and gate deposition) will remain unchanged with respect to a conventional CMOS process technology. This makes the present invention very cost attractive.

Aside from the CMOS technology, the present invention can be realized also with an High Electron Mobility Transistor structure including III-V materials in the fabrication process. This can be an attractive alternative to the Silicon MOSFET configuration in some particular applications.

Although the present invention has been described above with particularity, this was merely to teach one of ordinary skill in the art how to make and use the invention. Many additional modifications will fall within the scope of the invention. Thus, the scope of the invention is defined by the claims which immediately follow.

What is claimed is:

1. A semiconductor transistor structure for power integrated circuits comprising:
a multiplicity of semiconductor pillars directly coupled in parallel;
wherein the current flowing through said pillars when said semiconductor transistor is turned on, is orthogonal with respect to the primary surface of said integrated circuit.

2. The semiconductor structure of claim 1 wherein said semiconductor transistor comprises:
a semiconductor substrate of a first conductivity type;
at least one first region of a second conductivity type formed in said semiconductor substrate;
at least one second region of said second conductivity type formed on the upper portion of said semiconductor pillars;
at least one dielectric layer formed over at least a portion of the sidewalls of said semiconductor pillars;
at least one gate region covering at least a portion of the surface of at least one of said dielectric layers;
wherein said gate regions are directly coupled to a gate terminal of said semiconductor transistor;
wherein said first regions of said second conductivity type are directly coupled to a first terminal of said semiconductor transistor, and
wherein said second regions of said second conductivity type are directly coupled to a second terminal of said semiconductor transistor.

3. The semiconductor structure of claim 1 wherein said semiconductor transistor comprises a semiconductor substrate of a first conductivity type;
wherein at least one of said semiconductor pillars comprises a channel region of said first conductivity type.

4. The semiconductor structure of claim 1 wherein said semiconductor transistor comprises a semiconductor substrate of a first conductivity type;
wherein at least one of said semiconductor pillars comprises a channel region of said first conductivity type, and
wherein at least one of said channel regions of said semiconductor pillars is directly coupled to said semiconductor substrate.

5. The semiconductor structure of claim 1 wherein said semiconductor transistor comprises a semiconductor substrate of a first conductivity type;
wherein at least one of said semiconductor pillars comprises a channel region of said first conductivity type, and a region of a second conductivity type.

6. The semiconductor structure of claim 1 wherein said semiconductor transistor comprises:
a semiconductor substrate of a first conductivity type;
at least one dielectric layer formed over at least a portion of the sidewalls of said semiconductor pillars;
at least one gate region covering at least a portion of at least one of said dielectric layers;
wherein at least one of said semiconductor pillars comprises a region of a second conductivity type, and
wherein at least a portion of at least one of said gate regions is made of a semiconductor material of said first conductivity type.

7. The semiconductor structure of claim 1 wherein a cross-section of at least a portion of said semiconductor pillars is shaped in at least one of the geometric shapes belonging to the group comprising the triangular, the trapezoidal, the rectangular, the square, the octagonal, the hexagonal, the circular, and oval shapes.

8. The semiconductor structure of claim 1 wherein said semiconductor transistor is built in Semiconductor On Insulator technology.

9. The semiconductor structure of claim 1 wherein said semiconductor transistor is a hetero junction based high electron mobility transistor formed with semiconductor compounds comprising elements of the III and V groups of the periodic table.

10. A method for generating a semiconductor transistor for power integrated circuits comprising:
forming at least one semiconductor pillar in a semiconductor substrate of a first conductivity type, by means of etching or selective epitaxial growth process steps;
forming at least one first region of a second conductivity in said semiconductor substrate;
forming at least one second region of a second conductivity type on the upper part of said semiconductor pillars;
forming at least one dielectric layer by means of deposition or growth process steps, covering at least a portion of the sidewalls of said semiconductor pillars;
forming at least one gate region by means of deposition of metal or semiconductor material, covering at least a portion of one of said dielectric layers;
wherein at least one of said semiconductor pillars comprises a channel region of said first conductivity type;
wherein said gate regions are directly coupled to a gate terminal of said semiconductor transistor;
wherein said first regions of said second conductivity type are directly coupled to a first terminal of said semiconductor transistor;
wherein said second regions of said second conductivity type are directly coupled to a second terminal of said semiconductor transistor;
wherein at least a portion of the current flowing in said semiconductor transistor is orthogonal with respect to the primary surface of said semiconductor substrate.

11. The method of claim 10 wherein at least one of said channel regions of said semiconductor pillars is directly coupled to said semiconductor transistor.

12. The method of claim 10 wherein at least one of the channel regions of said semiconductor pillars comprises a region of said second conductivity type.

13. The method of claim 10 wherein at least one of said channel regions of said semiconductor pillars comprises a region of said second conductivity type, and at least a portion of at least one of said gate regions is made of a semiconductor material of said first conductivity type.

14. The method of claim 10 wherein a cross-section of at least a portion of said semiconductor pillars is shaped in at least one of the geometric shapes belonging to the group comprising the triangular, the trapezoidal, the rectangular, the square, the octagonal, the hexagonal, the circular, and oval shapes.

15. The method of claim 10 wherein said semiconductor transistor is built in Semiconductor On Insulator technology.

16. The method of claim 10 wherein said semiconductor transistor is a hetero junction based high electron mobility transistor formed with semiconductors compounds comprising elements of the III and V groups of the periodic table.
